(19) United States
(12) Patent Application Publication
(10) Pub. No.: US 2023/0124597 A1
(43) Pub. Date: Apr. 20, 2023

(54) SUBSTRATE PROCESSING METHOD AND SUBSTRATE PROCESSING APPARATUS

(71) Applicant: TOKYO ELECTRON LIMITED, Tokyo (JP)

(72) Inventors: Nobuhiro TAKAHASHI, Nirasaki City, Yamanashi (JP); Akitaka SHIMIZU, Nirasaki City, Yamanashi (JP); Yasuo ASADA, Nirasaki City, Yamanashi (JP)

(21) Appl. No.: 17/912,415

(22) PCT Filed: Mar. 5, 2021
(86) PCT No.: PCT/JP2021/008679

§ 371 Date: Sep. 16, 2022

(30) Foreign Application Priority Data
Mar. 19, 2020 (JP) 2020-048974

(51) Int. Cl. H01J 37/32

(52) U.S. Cl. CPC H01J 37/32449; H01J 37/32357; H01J 37/32816; H01J 2237/332; H01J 37/32724; H01J 2237/3346

(57) ABSTRACT

A method of processing a substrate in which a silicon layer and a silicon germanium layer are alternately stacked one above another, includes: forming an oxide film by selectively oxidizing a surface layer of an exposed surface of the silicon germanium layer using a gas containing fluorine and oxygen radicalized with a remote plasma; and removing the oxide film.

### TECHNICAL FIELD

The present disclosure relates to a substrate processing method and a substrate processing apparatus.

### BACKGROUND

Patent Document 1 discloses a method of etching a substrate in which silicon and silicon germanium are contained. According to the method disclosed in Patent Document 1, a ratio of a F₂ gas to a NH₃ gas is changed with an etching gas system including the F₂ gas and the NH₃ gas, so that a selective etching of the silicon germanium with respect to the silicon and a selective etching of the silicon with respect to the silicon germanium are performed.

### PRIOR ART DOCUMENT

### Patent Document

Patent Document 1: Japanese Laid-Open Patent Publication No. 2016-143781

A technique according to the present disclosure appropriately performs a selective etching of a silicon germanium layer with respect to a silicon layer in processing a substrate in which the silicon layer and the silicon germanium layer are alternately stacked one above another.

### SUMMARY

One aspect of the present disclosure is a method of processing a substrate in which a silicon layer and a silicon germanium layer are alternately stacked one above another, the method including forming an oxide film by selectively oxidizing a surface layer of an exposed surface of the silicon germanium layer using a gas containing fluorine and oxygen radicalized with a remote plasma, and removing the oxide film.

According to the present disclosure, a selective etching of a silicon germanium layer with respect to a silicon layer is appropriately performed in processing a substrate in which the silicon layer and the silicon germanium layer are alternately stacked one above another.

### BRIEF DESCRIPTION OF DRAWINGS

FIGS. 1A to 1D are explanatory diagrams schematically showing states of a wafer process in the related art.

FIG. 2 is a flowchart illustrating major steps of a wafer process according to the present embodiment.

FIGS. 3A to 3E are explanatory diagrams schematically showing states of the wafer process according to the present embodiment.

FIG. 4 is a longitudinal sectional view showing an example of a configuration of a plasma processing apparatus.

FIG. 5 is a graph illustrating a relationship between a plasma oxidation process time and an oxidation amount.

FIG. 6 is a longitudinal sectional view showing an example of a configuration of an etching processing apparatus.

FIG. 7 is an explanatory diagram showing an example of a wafer process result according to the present embodiment.

FIG. 8 is an explanatory diagram schematically showing a state of a wafer process according to another method.

### DETAILED DESCRIPTION

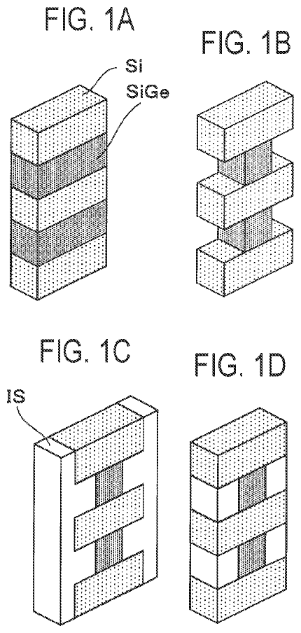

In a semiconductor device, a film that contains silicon is applied in a wide variety of applications. For example, a silicon germanium (SiGe) film or a silicon (Si) film is used for gate electrode, a channel material, or the like. In the related art, in a process of manufacturing a gate all around (GAA) transistor such as a nanosheet or a nanowire, as shown in FIGS. 1A to 1D, stacking of SiGe layers and Si layers on a substrate (wafer W) (FIG. 1A), selectively etching the SiGe layers (FIG. 1B), embedding an inner spacer (IS) as an insulating film (FIG. 1C), and etching the excess inner spacer (FIG. 1D) are sequentially performed. In addition, the insulating film embedded in FIG. 1C is configured as an insulating film for reducing a parasitic capacitance between a metal gate and a source/drain to be embedded in a subsequent process.

The technique disclosed in Patent Document 1 described above is a method of performing the selective etching on the SiGe layers in FIG. 1B. Specifically, by supplying a F₂ gas and a NH₃ gas as etching gases to the substrate placed inside a chamber, and controlling a volume ratio of the F₂ gas to the NH₃ gas, it is possible to perform the selective etching of the SiGe layers with respect to the Si layers.

On the other hand, such a selective etching of the SiGe layers requires to uniformly control an etching amount of each of the stacked SiGe layers. However, in the etching method disclosed in Patent Document 1, there may be a case in which it is difficult to uniformly control the etching amount of each SiGe layer due to etching conditions. That is, there is room for improvement in the selective etching of the SiGe layers in the related art.

A technique according to the present disclosure has been made in view of the above matters, and appropriately performs a selective etching of a silicon germanium layer with respect to a silicon layer in processing a substrate in which the silicon layer and the silicon germanium layer are alternately stacked one above another. Hereinafter, a wafer process as a substrate processing method according to the present embodiment will be described with reference to the drawings. In addition, in this specification and the accompanying drawings, elements having substantially the same functional configuration will be denoted by the same reference numerals, and redundant explanations thereof will be omitted.

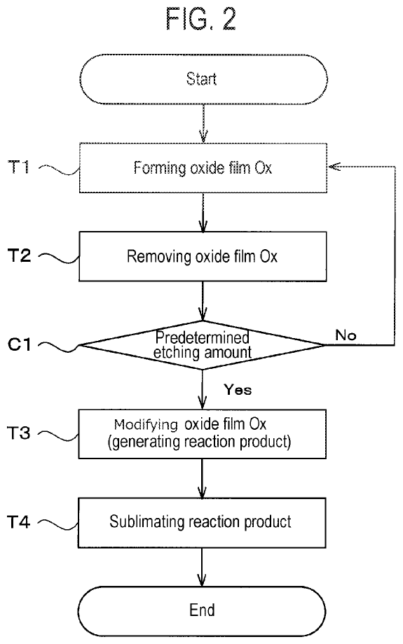

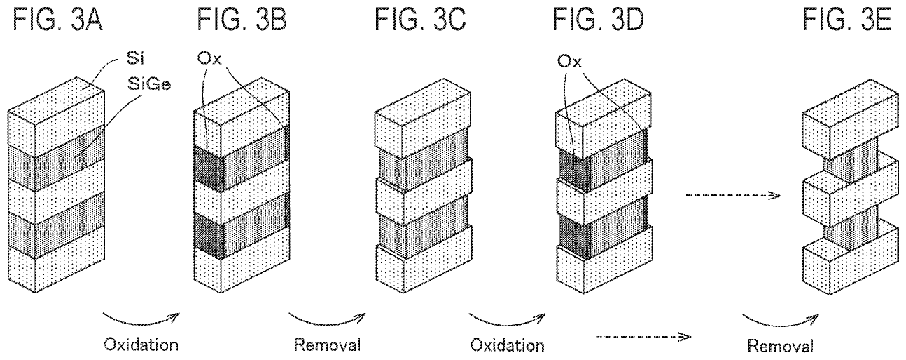

FIG. 2 is a flowchart illustrating major steps of a selective etching of a SiGe layer according to the present embodiment. Further, FIGS. 3A to 3E are explanatory diagrams showing major steps of the selective etching of the SiGe layer. In addition, in the following description, an exposed end surface (side surface) of each of a SiGe layer and a Si layer which are alternately arranged may be referred to as “exposed surface” of the SiGe layer and the Si layer.

As shown in FIG. 2 and FIGS. 3A to 3E, in the selective etching of the SiGe layer according to the present embodiment, selectively forming an oxide film Ox on a surface layer of the exposed surface of the SiGe layer among the Si layer and the SiGe layer stacked on the wafer W (step T1 of FIG. 2), and removing the oxide film Ox thus formed (step T2 of FIG. 2) are performed. These steps T1 and T2 are repeated until a desired etching amount is obtained in a depth direction from the exposed surface of the SiGe layer as shown in FIG. 3E (branch step C1 of FIG. 2).

After that, when the desired etching amount is obtained for the SiGe layer, the oxide film Ox that remains in the surface layer of the wafer W, more specifically, in the surface layers of the exposed surfaces of the Si layer and the SiGe layer is removed. Specifically, for example, a chemical oxide removal (COR) process of modifying the oxide film Ox to generate a reaction product (step T3 of FIG. 2), and a post heat treatment (PHT) process of sublimating the reaction product, which is generated by modifying the oxide film Ox in the COR process by heating the wafer W (step T4 of FIG. 2), are performed.

Hereinafter, a detailed method of each step shown in FIG. 2 and FIGS. 3A to 3E will be described.

### <Step T1: Formation of Oxide Film>

In step T1 of FIG. 2, the surface layer of the exposed surface of the SiGe layer is selectively oxidized by a plasma processing apparatus 1 as a plasma processor. As a result, the oxide film Ox (e.g., SiO₂ film) is formed in the depth direction from the exposed surface of the SiGe layer.

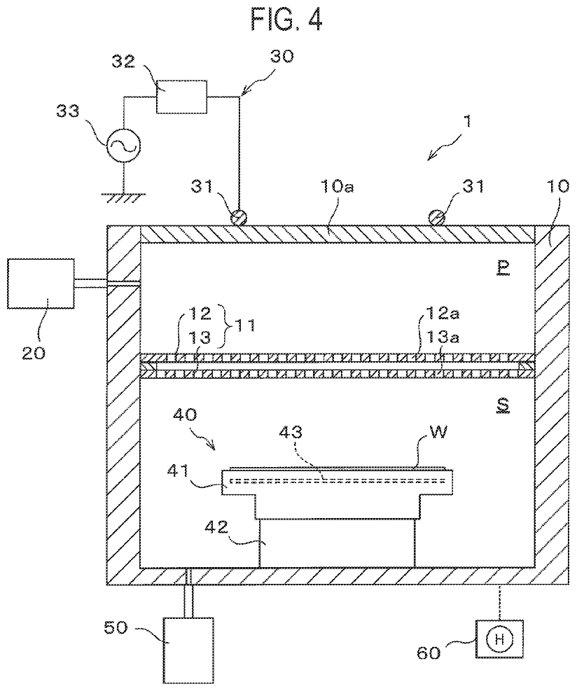

As shown in FIG. 4, the plasma processing apparatus 1 includes a hermetically sealed processing container 10 that accommodates the wafer W therein. The processing container 10 is made of, for example, aluminum or an aluminum alloy, and has an opened upper end. The upper end of the processing container 10 is sealed by a lid 10a that serves as a ceiling portion. A loading/unloading port (not shown) for the wafer W is provided in a side surface of the processing container 10. The processing container 10 is connected to the outside of the plasma processing apparatus 1 through the loading/unloading port. The loading/unloading port is configured to be opened or closed by a gate valve (not shown).

The interior of the processing container 10 is divided into an upper plasma generation space P and a lower processing space S by a partition plate 11. That is, the plasma processing apparatus 1 according to the present embodiment is configured as a remote plasma processing apparatus in which the plasma generation space P is separated from the processing space S.

The partition plate 11 includes at least two plate-shaped members 12 and 13 which are arranged from the plasma generation space P toward the processing space S so as to overlap each other with a gap therebetween. The plate-shaped members 12 and 13 have slits 12a and 13a formed to penetrate the respective members 12 and 13 in the overlapping direction, respectively. Further, the slits 12a and 13a are arranged so as not to overlap each other in a plan view, respectively. As a result, the partition plate 11 functions as a so-called ion trap that suppresses the permeation of ions in plasma into the processing space S when the plasma is generated in the plasma generation space P. More specifically, a labyrinth structure in which the slits 12a and the slits 13a are arranged so as not to overlap each other prevents the movement of anisotropically-moving ions while allowing isotropically-moving radicals to permeate therethrough.

The plasma generation space P includes an air supply part 20 that supplies a process gas into the processing container 10, and a plasma generator 30 that forms the process gas supplied into the processing container 10 into a plasma.

A plurality of gas sources (not shown) are connected to the air supply part 20 to supply the process gas including a fluorine-containing gas (e.g., NF₃ gas), an oxygen-containing gas (e.g., O₂ gas) and a dilution gas (e.g., Ar gas) to the interior of the processing container 10, respectively. In addition, the type of process gas supplied to the air supply part 20 is not limited thereto as long as the oxide film Ox can be formed on the surface layer of the exposed surface of the SiGe layer.

Further, the air supply part 20 is provided with a flow rate regulator (not shown) that regulates an amount of the process gas supplied to the plasma generation space P. The flow rate regulator includes, for example, an on-off valve and a mass flow controller.

The plasma generator 30 is configured as an inductively coupled device using an RF antenna. The lid 10a of the processing container 10 is made of, for example, a quartz plate, and is configured as a dielectric window. An RF antenna 31 is formed above the lid 10a to generate an inductively coupled plasma in the plasma generation space P of the processing container 10. The RF antenna 31 is connected to a radio frequency power supply 33 via a matcher 32 equipped with a matching circuit for matching impedance on a power supply side and impedance on a load side. The radio frequency power supply 33 outputs any output value of radio frequency power having a certain frequency suitable for plasma generation (usually, 13.56 MHz or more).

The processing space S includes a stage 40 provided inside the processing container 10 and on which the wafer W is placed, and an exhaust part 50 that discharges the process gas inside the processing container 10.

The stage 40 includes an upper stage 41 on which the wafer W is placed, and a lower stage 42 fixed to a bottom surface of the processing container 10 to support the upper stage 41. A temperature regulation mechanism 43 is provided inside the upper stage 41 to regulate a temperature of the wafer W.

The exhaust part 50 is connected to, for example, an exhaust mechanism (not shown) such as a vacuum pump, via an exhaust pipe provided in a bottom portion of the processing container 10. Further, the exhaust pipe is provided with an automatic pressure control valve (APC). An internal pressure of the processing container 10 is controlled by the exhaust mechanism and the automatic pressure control valve.

The plasma processing apparatus 1 described above is provided with a control device 60 as a controller. The control device 60 is, for example, a computer equipped with a CPU, a memory, and the like, and includes a program storage (not shown). A program for controlling the process of the wafer W in the plasma processing apparatus 1 is stored in the program storage. In addition, the program was recorded on a computer-readable storage medium H, and may be installed from the storage medium H to the control device 60.

The plasma processing apparatus 1 is configured as described above. Next, a plasma oxidation process (formation of the oxide film Ox) performed by the plasma processing apparatus 1 will be described. In addition, the Si layer and the SiGe layer are formed in advance on the wafer W to be loaded into the plasma processing apparatus 1 while being alternately stacked one above another.

First, as shown in FIG. 3A, the wafer W on which the Si layer and the SiGe layer are alternately stacked one above another is placed on the stage 40. As shown in FIG. 3B, on the wafer W loaded into the plasma processing apparatus 1, the oxide film Ox is formed on the surface layer of the exposed surface of the SiGe layer.

Specifically, when the wafer W is placed on the stage 40, the process gas (the NF₃ gas, the O₂ gas and the Ar gas in the present embodiment) is supplied from the air supply part 20 to the plasma generation space P, and the radio frequency power is supplied to the RF antenna 31 to generate a plasma containing oxygen and fluorine as the inductively coupled plasma. In other words, the generated plasma contains oxygen radicals (O*) and fluorine radicals (F*).

Here, flow rates of the process gases supplied to the plasma generation space P may be O₂:NF₃=100 sccm to 2,500 sccm:1 sccm to 20 sccm. More specifically, the volume ratio of the NF₃ gas to the O₂ gas may be 0.1 vol % or more and 1.0 vol % or less. Further, the output of the radio frequency power in the plasma generation space P may be 100 W to 1,000 W, and the internal pressure (degree of vacuum) of the plasma generation space P may be 6.67 Pa to 266.6 Pa (50 mTorr to 2,000 mTorr). Further, in this case, the temperature of the wafer W placed on the stage 40 may be controlled to 0 degrees C. to 120 degrees C., more specifically, 15 degrees C. to 100 degrees C.

The plasma generated in the plasma generation space P is supplied to the processing space S through the partition plate 11. In this case, since the partition plate 11 is formed to have the labyrinth structure as described above, only the radicals generated in the plasma generation space P are allowed to penetrate to the processing space S. When the radicals penetrate to the processing space S, impurities adhering to the surface of the wafer W are removed by F*. Then, O* is applied to the SiGe layer so that the surface layer of the exposed surface of the SiGe layer is oxidized to form the oxide film Ox (SiO₂ film) on the surface layer of the exposed surface. In this case, O₂ bonds to Si other than Ge in the oxidation of the SiGe layer. As a result, Ge is gasified (turned into, for example, Ge₂F₄ or GeOF₂) to be scattered. The gasified Ge gas is carried to the exhaust part 50 by, for example, F* or Ar*, and is recovered.

Here, in the plasma oxidation process according to the present embodiment, oxidation occurs not only in the surface layer of the exposed surface of the SiGe layer, but also in the surface layer of the exposed surface of the Si layer to form the oxide film Ox (SiO₂ film). However, as a result of extensive research conducted by the present inventors, it was found that an oxidation rate of the SiGe layer is higher than that of the Si layer (e.g., by about 10 times). In other words, in the plasma oxidation process according to the present embodiment, a thickness of the oxide film Ox formed on the Si layer is smaller (e.g., about 1/10) than that of the oxide film Ox formed on the SiGe layer. This makes it possible to appropriately perform the selective oxidation of the SiGe layer.

Further, in the plasma oxidation process according to the present embodiment, only the isotropically-moving radicals penetrate to the processing space S as described above. Therefore, the thickness of the oxide film Ox formed by the plasma oxidation process is made uniform in the plane of the wafer W and also uniform in each of the stacked SiGe layers. In other words, a variation in the thickness of the formed oxide film Ox, in particular, a variation in the thickness of the oxide film Ox formed in the surface layer of the exposed surface of each of the SiGe layers stacked one above another may be reduced.

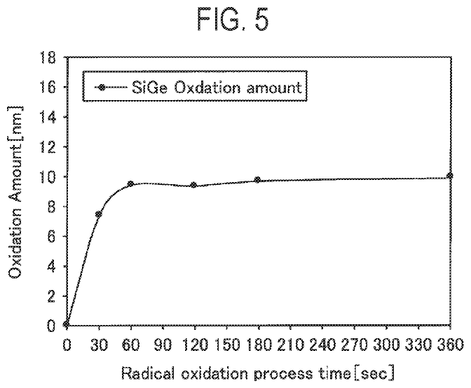

Further, the plasma oxidation process according to the present embodiment is a process in which the oxidation amount of the SiGe layer, in other words, the thickness of the formed oxide film Ox from the exposed surface is saturated during the process time in the plasma processing apparatus 1. In the present embodiment, the thickness of the oxide film Ox formed by one round of plasma oxidation process is, for example, about 10 nm, as shown in FIG. 5.

In addition, the saturation oxidation amount of the SiGe layer (saturation formation thickness of the oxide film Ox) shown in FIG. 5 is determined by a depth at which the radicals reach the SiGe layer. In other words, the saturation oxidation amount of the SiGe layer may be controlled by controlling the internal pressure of the plasma processing apparatus 1 to control the reaching depth of the radicals to the SiGe layer. Specifically, for example, when the internal pressure of the plasma processing apparatus 1 is raised, the saturation oxidation amount may be increased, that is, the thickness of the formed oxide film Ox may be increased. Further, for example, when the internal pressure of the plasma processing apparatus 1 is lowered, the saturation oxidation amount may be reduced, that is, the thickness of the formed oxide film Ox may be reduced.

In addition, as the process time in the plasma processing apparatus 1 becomes longer, the radicals supplied to the processing space S may act more strongly on the Si layer. Thus, the oxidation amount of the Si layer, that is, the thickness of the oxide film Ox formed in the surface layer of the exposed surface of the Si layer may be increased. The selective etching of the SiGe layer according to the present embodiment is performed by removing the formed oxide film Ox as described later. As described above, in the case in which the oxidation amount of the Si layer is increased, since the oxidation amount of the SiGe layer is saturated regardless of the process time as described above, the selectivity of the SiGe layer (a ratio of the oxidation amount of the SiGe layer to the oxidation amount of the Si layer) degrades.

Therefore, in order to minimize the effect of the radicals on the Si layer, it is desirable in the plasma oxidation process according to the present embodiment to stop the supply of the process gas to the processing container 10 before the oxidation amount of the SiGe layer reaches the saturation oxidation amount. This makes it possible to appropriately prevent the degradation in the selectivity of the SiGe layer. Further, even when the supply of the process gas is stopped before the oxidation amount of the SiGe layer reaches the saturation oxidation amount, the oxidation of the SiGe layer may proceed by the process gas (plasma) remaining inside the processing container 10, which makes it possible to appropriately bring the oxidation amount of the SiGe layer close to the saturation oxidation amount.

### <Step T2: Removal of Oxide Film>

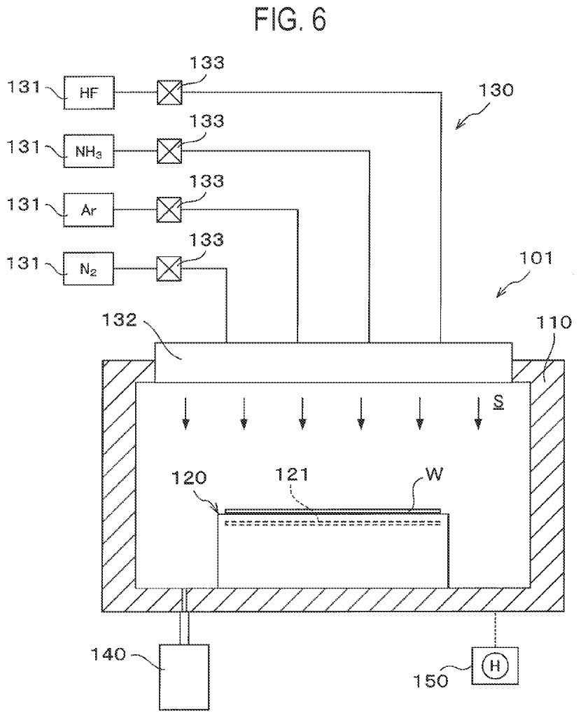

After the oxide film Ox is formed in the surface layer of the exposed surface of the SiGe layer, removing the oxide film Ox formed in step T1 using an etching processing apparatus 101 as a removing part, for example, a gas etching is performed. FIG. 6 is a longitudinal sectional view schematically showing a configuration of the etching processing apparatus 101 for removing the oxide film Ox.

As shown in FIG. 6, the etching processing apparatus 101 includes a hermetically sealed processing container 110 that accommodates the wafer W. A processing space S is defined inside the processing container 110. A loading/unloading port (not shown) for the wafer W is provided in a side surface of the processing container 110. The processing container 110 is connected to the outside of the etching processing apparatus 101 through this loading/unloading port. The loading/unloading port is configured to be opened or closed by a gate valve (not shown). In addition, the etching processing apparatus 101 includes a stage 120 provided inside the processing container 110 and on which the wafer W is placed, a supply part 130 that supplies an etching gas into the processing space S, and an exhaust part 140 that discharges the etching gas inside the processing container 110.

The stage 120 is provided to be fixed to a bottom surface of the processing container 110. A wafer holding surface that holds the wafer W is formed on an upper surface of the stage 120. A temperature regulation mechanism 121 is provided inside the stage 120 to regulate a temperature of the wafer W held on the wafer holding surface.

The supply part 130 includes a plurality of gas sources 131 that supply a fluorine-containing gas (e.g., HF gas), an ammonia (NH₃) gas, a dilution gas (e.g., Ar gas), and an inert gas (e.g., N₂ gas) as etching gases to the interior of the processing container 110, respectively, and a shower head 132 provided at a ceiling portion of the processing container 110 and having a plurality of discharge holes through which the etching gas is discharged into the processing space S. The gas sources 131 are connected to the interior of the processing container 110 via supply pipes connected to the shower head 132.

Further, the supply part 130 is provided with a flow rate regulator 133 that regulates a supply amount of the etching gas to the interior of the processing container 110. The flow rate regulator 133 includes, for example, an on-off valve and a mass flow controller.

The exhaust part 140 is connected to, for example, an exhaust mechanism (not shown) such as a vacuum pump via an exhaust pipe provided at the bottom portion of the processing container 110. Further, the exhaust pipe is provided with an automatic pressure control valve (APC). An internal pressure of the processing container 110 is controlled by the exhaust mechanism and the automatic pressure control valve.

The etching processing apparatus 101 described above is provided with a control device 150 as a controller. The control device 150 is, for example, a computer equipped with a CPU, a memory, and the like, and includes a program storage (not shown). A program for controlling the process of the wafer W in the etching processing apparatus 101 is stored in the program storage. In addition, the program was recorded on a computer-readable storage medium H and may be installed from the storage medium H on the control device 150.

In addition, the control device 150 provided in the etching processing apparatus 101 may be the same as the control device 60 provided in the plasma processing apparatus 1. That is, the etching processing apparatus 101 may be connected to the control device 60 provided in the plasma processing apparatus 1 instead of the control device 150.

The etching processing apparatus 101 is configured as described above. Next, a gas etching process (removal of the oxide film Ox) performed by the etching processing apparatus 101 will be described. In addition, in the wafer W loaded into the etching processing apparatus 101, the oxide film Ox is formed previously on the surface layer of the exposed surface of the SiGe layer in step T1 described above.

First, as shown in FIG. 3B, the wafer W having the oxide film Ox formed in the surface layer of the exposed surface of the SiGe layer is placed on the stage 120. The oxide film Ox is removed from the wafer W loaded into the etching processing apparatus 101 as shown in FIG. 3C.

Specifically, when the wafer W is placed on the stage 120 and the interior of the processing container 110 is hermetically sealed, first, the dilution gas (Ar gas) and the inert gas (N₂ gas) are supplied to the processing space S. At this time, the internal pressure of the processing space S is controlled to, for example, 30 mTorr to 5,000 mTorr, and the temperature of the wafer W on the stage 120 is controlled to, for example, 0 degrees C. to 150 degrees C.

When the internal pressure of the processing space S and the temperature of the wafer W reach desired values, the fluorine-containing gas (HF gas) and the NH₃ gas are further supplied to the processing space S. At this time, the flow rates of the HF gas and the NH₃ gas supplied to the processing space S are controlled to, for example, 10 sccm to 1,000 sccm, respectively, and the flow rates of the Ar gas and the N₂ gas are controlled to, for example, 0 sccm to 1,000 sccm, respectively. Then, with the supply of the HF gas and the NH₃ gas to the processing space S, the gas etching process of the oxide film Ox formed on the surface layer of the exposed surface of the SiGe layer is started.

Here, in the gas etching process according to the present embodiment, the oxide film Ox formed in step T1 is selectively removed due to the difference between the etching rates of the oxide film Ox (SiO₂ film), the Si layer and the SiGe layer. In other words, since the oxide film Ox is selectively formed on the SiGe layer due to the difference between the oxidation rates of the Si layer and the SiGe layer in step T1, the selective etching removal of the SiGe layer may be appropriately performed in the gas etching process according to the present embodiment.

Further, as described above, in the plasma oxidation process of step T1, the thickness of the formed oxide film Ox may be made uniform in the plane of the wafer W and also uniform in each of the stacked SiGe layers. That is, in the gas etching process according to the present embodiment, the removal of the SiGe layer may be performed uniformly in the plane of the wafer W and also uniformly performed in each of the stacked SiGe layers.

Further, in the plasma oxidation process of step T1, as shown in FIG. 5, the thickness of the oxide film Ox formed by one round of plasma oxidation process is saturated regardless of the process time. That is, since the etching amount of the SiGe layer in one round of gas etching process is saturated to coincide with the thickness of the formed oxide film Ox, the etching amount of the SiGe layer may be easily controlled. Further, at this time, since the thickness of the formed oxide film Ox may be controlled by the internal pressure of the plasma processing apparatus 1 as described above, the etching amount of the SiGe layer may be more appropriately controlled.

### <Branch C1: Repetition of Formation and Removal of Oxide Film>

The formation of the oxide film Ox (step T1) and the removal of the oxide film Ox (step T2) (that is, the removal of the SiGe layer) according to the present embodiment are performed as described above. Here, as described above, the oxidation amount of the SiGe layer (the etching amount of the SiGe layer) according to the present embodiment is saturated regardless of the plasma process time as shown in FIG. 5. That is, the etching amount of the SiGe layer may not be obtained by a desired level through one round of the formation and removal of the oxide film Ox. For this reason, in the selective etching method of the SiGe layer according to the present embodiment, a wafer process cycle including the formation of the oxide film Ox (step T1) and the removal of the oxide film Ox (step T2) is repeated to etch away the SiGe layer at a desired depth.

In other words, the number of wafer process cycles repeated in the present embodiment is determined according to a required total etching amount of the SiGe layer.

As described above, even when a series of wafer process cycles are repeated, the total etching amount of the SiGe layer may be easily controlled since the etching amount of the SiGe layer in one cycle coincides with the saturation oxidation amount of the SiGe layer. Further, at this time, since the saturation oxidation amount of the SiGe layer is controlled by the internal pressure of the plasma processing apparatus 1 as described above, the total etching amount of the SiGe layer may be more appropriately controlled. Further, since the total etching amount of the SiGe layer may be appropriately controlled as described above, a line width of the SiGe layer after the selective etching process of the SiGe layer, that is, a channel width formed in a subsequent step may be controlled to an arbitrary dimension.

When the total etching amount of the SiGe layer is obtained by the desired level by repeating the cycle of the formation and removal of the oxide film, the oxide film (Ox) remaining in the surface layer of the wafer W, in particular, in the surface layer of the exposed surface of the Si layer and the SiGe layer, is removed before the wafer W is subjected to the subsequent step. A method of removing the oxide film Ox is not particularly limited, and may be performed by, for example, dry etching, wet etching or the like. In the following description, a case in which the wafer W is sequentially subjected to the COR process and the PHT process will be described by way of example.

<Step T3: Modification of Oxide film (Generation of Reaction Product)>

In step T3 of FIG. 2, an etching gas is applied to the oxide film Ox remaining in the surface layer of the exposed surface of the Si layer and the SiGe layer by a COR processing apparatus as a removing part. As a result, the oxide film Ox is modified to generate a reaction product (COR process).

The COR processing apparatus (not shown) has, for example, a configuration equivalent to that of the etching processing apparatus 101 shown in FIG. 6. That is, the COR processing apparatus includes, for example, a processing container having the processing space S defined therein, a stage provided inside the processing container and on which the wafer W is placed, a supply that supplies an etching gas to the processing space S, and an exhaust part that discharges the process gas in the processing container. In other words, the COR process according to the present embodiment may be performed in the etching processing apparatus 101 that performs the gas etching process of step T2.

In the COR process according to the present embodiment, first, the wafer W on which the SiGe layer has been selectively etched in steps T1 and T2 is placed on the stage. Subsequently, the dilution gas (Ar gas) and the inert gas (Na gas) are supplied to the interior of the hermetically sealed processing container, such that the internal pressure of the processing container is controlled to, for example, 30 mTorr to 5,000 mTorr, and the temperature of the wafer W on the stage is controlled to, for example, 0 degrees C. to 150 degrees C.

When the internal pressure of the processing space S and the temperature of the wafer W reach desired values, the fluorine-containing gas (HF gas) and the NH₃ gas are further supplied to the processing space S. At this time, the flow rates of the HF gas and the NH₃ gas supplied into the processing space S are controlled to, for example, 50 sccm to 500 sccm, respectively, and the flow rates of the Ar gas and the Na gas are controlled to, for example, 100 sccm to 600 sccm, respectively. Then, the HF gas and the NH₃ gas supplied to the processing space S are applied to the oxide film Ox remaining on the surface of the wafer W, so that the oxide film Ox is modified into an ammonium fluoride based compound as a reaction product.

### <Step T4: Sublimation of Reaction Product>

After the oxide film Ox is modified in step T3, the reaction product (ammonium fluoride based compound) generated by the modification of the oxide film Ox is sublimated (PHT process) using a PHT processing apparatus as a removing part.

The PHT processing apparatus (not shown) has, for example, a configuration equivalent to that of the COR processing apparatus. That is, the PHT processing apparatus includes, for example, a processing container having the processing space S defined therein, a stage provided inside the processing container and on which the wafer W is placed, a supply that supplies an etching gas to the processing space S, and an exhaust part that discharges the process gas in the processing container. In other words, the PHT process according to the present embodiment may be performed in the COR processing apparatus that performs the COR process of step T3. Further, in other words, the removal of the oxide film Ox in step T2, the COR process in step T3, and the PHT process in step T4 may be performed in the same etching processing apparatus 101, respectively.

In the PHT process according to the present embodiment, first, the wafer W subjected to the COR process in step T3 is placed on the stage. Subsequently, the inert gas (N₂ gas) is supplied as the process gas to the interior of the hermetically sealed processing container, and the temperature of the wafer W on the stage is controlled to, for example, 85 degrees C. or higher. The ammonium fluoride based compound, which is a reaction product generated in the COR process, is sublimed by heat. That is, the ammonium fluoride based compound generated in the COR process of step T3, that is, the modified oxide film Ox, may be sublimated and removed by raising the temperature of the wafer W. In addition, the sublimated reaction product is further recovered in the exhaust part 50 along with the process gas (the N₂ gas), for example.

In addition, the modification of the oxide film Ox in step T3 and the sublimation of the reaction product generated by the modification of the oxide film Ox in step T4 may be repeated until the ammonium fluoride based compound as the reaction product is removed. Then, when the oxide film Ox remaining in the surface layer of the wafer W, in particular, in the surface layer of the exposed surface of the Si layer and the SiGe layer, is removed, the series of the selective etching of the SiGe layer according to the present embodiment is completed.

<Effects of Wafer Process according to the Present Embodiment>

According to the present embodiment, the oxide film Ox may be formed on the SiGe layer uniformly in the plane of the wafer W and uniformly in each of the stacked SiGe layers by using the process gas radicalized with the remote plasma. Further, the SiGe layer is etched through the removal of the formed oxide film Ox as described above, so that the etching amount of the SiGe layer may be made uniform in the plane of the wafer W and uniform in each of the stacked SiGe layers. That is, it is possible to reduce a variation in the etching amount of each of the stacked SiGe layers.

According to the present embodiment, the SiGe layer may be selectively oxidized by the difference between the oxidation rates of the Si layer and the SiGe layer, and the oxide film Ox may be selectively etched by the difference between the etching rates of the oxide film Ox (SiO₂ film), the Si layer and the SiGe layer. That is, according to the present embodiment, it is possible to appropriately perform the selective etching process of the SiGe layer.

Further, with the plasma oxidation process according to the present embodiment, it is possible to easily control the etching amount of the SiGe layer involved in the removal of the oxide film Ox since the thickness of the formed oxide film Ox is saturated regardless of the process time. Further, at this time, since the thickness of the formed oxide film Ox is controlled by the internal pressure of the plasma processing apparatus that performs the plasma oxidation process, it is possible to more appropriately control the etching amount of the SiGe layer.

Furthermore, according to the present embodiment, the formation of the oxide film Ox on the surface layer of the exposed surface of the SiGe layer and the removal of the formed oxide film (Ox) are repeated, so that the SiGe layer may be easily removed by a desired total etching amount. Further, at this time, the thickness of the formed oxide film Ox is controlled by the internal pressure of the plasma processing apparatus that performs the plasma oxidation process, so that the total etching amount of the SiGe layer may be more appropriately controlled.

In addition, although the oxide film Ox (SiO₂ film) formed in the surface layer of the exposed surface of the SiGe layer has been described to be removed by the gas etching process using the fluorine-containing gas (HF gas) and the ammonia (NH₃) gas in the above embodiments, the method of removing the oxide film Ox is not limited thereto. As an example, the oxide film Ox formed in the surface layer of the exposed surface of the SiGe layer may be removed by wet etching, or may be removed by performing, for example, the COR process and PHT process described above.

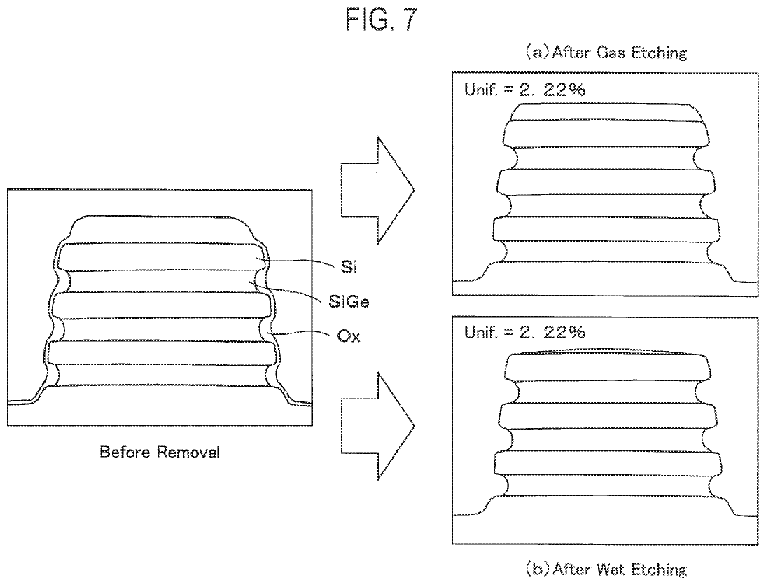

FIG. 7 illustrates an example of a process result in the case in which the SiGe layer is selectively etched according to the present embodiment. In the present example, first, the oxide film Ox was selectively formed in the surface layer of the exposed surface of the SiGe layer by using the process gas radicalized with the remote plasma as described above. In FIG. 7, (a) illustrates a process result obtained when the oxide film Ox was removed by the gas etching process using the fluorine-containing gas (HF gas) and the ammonia (NH₃) gas as illustrated in the above embodiments, and (b) illustrates a process result obtained when the oxide film Ox was removed by wet etching.

As shown the process results (a) and (b) in FIG. 7, it was found that, by forming the oxide film Ox by the process gas radicalized with the remote plasma as illustrated in the present embodiment, the etching amount (EA) from the exposed surface of the SiGe layer can be uniformly controlled. Specifically, as shown in FIG. 7, the variation in the etching amount of each of the stacked SiGe layers was about 2.2%. As described above, with the selective etching method of the SiGe layer according to the present embodiment, it is possible to appropriately reduce the variation in the total etching amount of each of the stacked SiGe layers.

In addition, although the plasma oxidation process in step T1 and the etching removal process of the oxide film Ox in step T2 have been described to be performed in the plasma processing apparatus 1 and the etching processing apparatus 101 according to the above embodiment, respectively, both the plasma oxidation process and the etching removal process may be performed in the same processing container. That is, for example, when the plasma processing apparatus 1 is configured to be able to supply the HF gas and the NH₃ gas as an etching gas to the processing space S, the plasma processing apparatus 1 may perform the etching removal of the oxide film Ox.

Further, as described above, the etching removal process in step T2, the COR process in step T3, and the PHT process in step T4 may be performed in the same processing container (etching processing apparatus 101). In other words, when the plasma processing apparatus 1 is configured to be able to perform the etching removal of the oxide film Ox as described above, a series of wafer processes related to steps T1 to T4 of FIG. 2 may be performed in the same processing container.

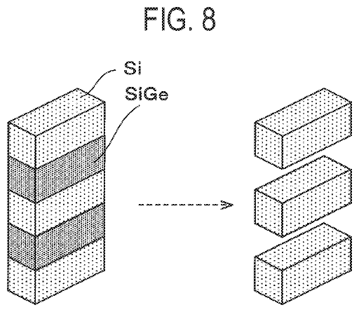

In addition, although the case in which the surface layer of the SiGe layer is removed at a desired depth as shown in FIGS. 3A to 3E by the selective etching of the SiGe layer has been described by way of example in the above embodiment, the SiGe layer may be completely removed as shown in FIG. 8. Even in such a case, it is possible to appropriately perform the selective etching of the SiGe layer by applying the method according to the present embodiment. Further, in this case, as described above, the supply of the process gas to the processing container is stopped before the oxidation amount of the SiGe layer reaches the saturation oxidation amount, and the time of the plasma oxidation process is controlled such that the oxidation amount of the SiGe layer reaches the saturation oxidation amount by the process gas remaining inside the processing container. This makes it possible to appropriately shorten the time required for the wafer process cycles to be performed repeatedly.

The embodiments disclosed herein should be considered to be exemplary and not limitative in all respects. The above embodiments may be omitted, replaced or modified in various forms without departing from the scope of the appended claims and their gist.

In addition, the following configurations also belong to the technical scope of the present disclosure.

(1) A method of processing a substrate in which a silicon layer and a silicon germanium layer are alternately stacked one above another, the method including: forming an oxide film by selectively oxidizing a surface layer of an exposed surface of the silicon germanium layer using a gas containing fluorine and oxygen radicalized with a remote plasma; and removing the oxide film

According to (1) above, it is possible to uniformly form an oxide film on each of the stacked silicon germanium layers by using the gas radicalized with the remote plasma. Further, it is possible to reduce a variation in an etching amount of each of the stacked silicon germanium layers by removing the silicon germanium layer through the removal of the oxide film thus formed.

(2) In the method described in (1) above, the gas used to form the oxide film contains an O₂ gas and a fluorine-containing gas, and a volume ratio of the fluorine-containing gas to the O₂ gas is 0.1 vol % or more and 1.0 vol % or less.

(3) In the method described in (1) or (2) above, a thickness of the oxide film is controlled by an internal pressure of a plasma processing part configured to form the oxide film.

(4) In the method described in any one of (1) to (3) above, a thickness of the oxide film is saturated regardless of a process time of the forming the oxide film, and in the forming the oxide film, the gas is supplied to a plasma processing part configured to form the oxide film before the thickness of the oxide film is saturated.

(5) In the method described in any one of (1) to (4) above, a cycle including the forming the oxide film and the removing the oxide film is repeated.

According to (5) above, it is possible to appropriately control a total etching amount of the silicon germanium layer by repeating the forming the oxide film and the removing the oxide film.

(6) In the method described in any one of (1) to (5) above, the removing the oxide film includes modifying the oxide film into a reaction product, and heating the substrate and sublimating the reaction product generated by modifying the oxide film.

(7) In the method described in any one of (1) to (6) above, the removing the oxide film is performed using a gas containing at least an HF gas and an NH₃ gas.

(8) An apparatus for processing a substrate in which a silicon layer and a silicon germanium layer are alternately stacked one above another, comprises: a plasma processing part configured to form an oxide film by selectively oxidizing a surface layer of an exposed surface of the silicon germanium layer using a gas containing fluorine and oxygen radicalized with a remote plasma; a removing part configured to remove the oxide film; and a controller configured to control operations of the plasma processing part and the removing part.

(9) In the apparatus described in (8) above, the gas used to form the oxide film contains an O₂ gas and a fluorine-containing gas, and the controller controls the operation of the plasma processing part such that a volume ratio of the fluorine-containing gas to the O₂ gas is 0.1 vol % or more and 1.0 vol % or less.

(10) In the apparatus described in (8) or (9) above, the controller controls a thickness of the oxide film based on an internal pressure of the plasma processing part.

(11) In the apparatus described in any one of (8) to (10) above, a thickness of the oxide film is saturated regardless of a process time in the plasma processing part, and the controller controls the operation of the plasma processing part so as to stop supplying the gas to the plasma processing part before the thickness of the oxide film is saturated.

(12) In the apparatus described in any one of (8) to (11) above, the controller controls the operations of the plasma processing part and the removing part so as to repeat a cycle including the formation of the oxide film by the plasma processing part and the removal of the oxide film by the removing part.

(13) In the apparatus described in any one of (8) to (12) above, the controller controls the operation of the removing part such that the oxide film is modified into a reaction product, the substrate is heated, and the reaction product generated by modifying the oxide film is sublimated.

(14) In the apparatus described in any one of (8) to (13) above, the controller controls the operation of the removing part so as to remove the oxide film by using a gas containing at least an HF gas and an NH₃ gas.

### EXPLANATION OF REFERENCE NUMERALS

Ox: oxide film, Si: silicon, SiGe: silicon germanium, W: wafer

1-14. (canceled)

15. A method of processing a substrate in which a silicon layer and a silicon germanium layer are alternately stacked one above another, the method comprising:
forming an oxide film by selectively oxidizing a surface layer of an exposed surface of the silicon germanium layer using a gas containing fluorine and oxygen radicalized with a remote plasma; and
removing the oxide film.

16. The method of claim 15, wherein the gas used to form the oxide film contains an O₂ gas and a fluorine-containing gas, and a volume ratio of the fluorine-containing gas to the O₂ gas is 0.1 vol % or more and 1.0 vol % or less.

17. The method of claim 16, wherein a thickness of the oxide film is controlled by an internal pressure of a plasma processing part configured to form the oxide film.

18. The method of claim 17, wherein a thickness of the oxide film is saturated regardless of a process time of the forming the oxide film, and
in the forming the oxide film, the gas is supplied to a plasma processing part configured to form the oxide film before the thickness of the oxide film is saturated.

19. The method of claim 18, wherein a cycle including the forming the oxide film and the removing the oxide film is repeated.

20. The method of claim 19, wherein the removing the oxide film includes:
modifying the oxide film into a reaction product; and
heating the substrate and sublimating the reaction product generated by modifying the oxide film.

21. The method of claim 20, wherein the removing the oxide film is performed using a gas containing at least an HF gas and an NH₃ gas.

22. The method of claim 15, wherein a thickness of the oxide film is controlled by an internal pressure of a plasma processing part configured to form the oxide film.

23. The method of claim 15, wherein a thickness of the oxide film is saturated regardless of a process time of the forming the oxide film, and
in the forming the oxide film, the gas is supplied to a plasma processing part configured to form the oxide film before the thickness of the oxide film is saturated.

24. The method of claim 15, wherein a cycle including the forming the oxide film and the removing the oxide film is repeated.

25. An apparatus for processing a substrate in which a silicon layer and a silicon germanium layer are alternately stacked one above another, comprising:
a plasma processing part configured to form an oxide film by selectively oxidizing a surface layer of an exposed surface of the silicon germanium layer using a gas containing fluorine and oxygen radicalized with a remote plasma;
a removing part configured to remove the oxide film; and
a controller configured to control operations of the plasma processing part and the removing part.

26. The apparatus of claim 25, wherein the gas used to form the oxide film contains an O₂ gas and a fluorine-containing gas, and
the controller controls the operation of the plasma processing part such that a volume ratio of the fluorine-containing gas to the O₂ gas is 0.1 vol % or more and 1.0 vol % or less.

27. The apparatus of claim 26, wherein the controller controls a thickness of the oxide film based on an internal pressure of the plasma processing part.

28. The apparatus of claim 27, wherein a thickness of the oxide film is saturated regardless of a process time in the plasma processing part, and
the controller controls the operation of the plasma processing part so as to stop supplying the gas to the plasma processing part before the thickness of the oxide film is saturated.

29. The apparatus of claim 28, wherein the controller controls the operations of the plasma processing part and the removing part so as to repeat a cycle including the formation of the oxide film by the plasma processing part and the removal of the oxide film by the removing part.

30. The apparatus of claim 29, wherein the controller controls the operation of the removing part such that the oxide film is modified into a reaction product, the substrate is heated, and the reaction product generated by modifying the oxide film is sublimated.

31. The apparatus of claim 30, wherein the controller controls the operation of the removing part so as to remove the oxide film by using a gas containing at least an HF gas and an NH₃ gas.

32. The apparatus of claim 25, wherein the controller controls a thickness of the oxide film based on an internal pressure of the plasma processing part.

33. The apparatus of claim 25, wherein a thickness of the oxide film is saturated regardless of a process time in the plasma processing part, and
the controller controls the operation of the plasma processing part so as to stop supplying the gas to the plasma processing part before the thickness of the oxide film is saturated.

34. The apparatus of claim 25, wherein the controller controls the operations of the plasma processing part and the removing part so as to repeat a cycle including the formation of the oxide film by the plasma processing part and the removal of the oxide film by the removing part.
